(19) United States
(12) Patent Application Publication
(10) Pub. No.: US 2026/0299015 A1
(43) Pub. Date: Oct. 1, 2026

(54) DUAL MODE HIGH SPEED LOOPBACK WITH VOLTAGE LEVEL SHIFTING AND MULTIPLEXING

(71) Applicants: Advanced Micro Devices, Inc., Santa Clara, CA (US); XILINX, INC., San Jose, CA (US)

(72) Inventors: Dinesh CHERUKUMUDI, Bangalore (IN); Dinakar Venkata SARRAJU, Bangalore (IN); Chuen-Huei CHOU, San Jose, CA (US); Morampudi MOUNIKA, Bangalore (IN)

(21) Appl. No.: 19/091,576

(22) Filed: Mar. 26, 2025

(51) Int. Cl. G01R 31/28; H03F 3/04; H03K 19/00

(52) U.S. Cl. CPC G01R 31/2884; H03F 3/04; H03K 19/0005

(57) ABSTRACT

A loopback testing circuitry comprises a pre-driver circuitry. The pre-driver circuitry comprises a first source follower (SF) circuitry, and a loopback circuitry electronically connected to the pre-driver circuitry. The loopback circuitry comprises a second SF circuitry and a current mode logic (CML) amplifier circuitry, wherein outputs of the first SF circuitry and outputs of the second SF circuitry are each electrically connected to the CML amplifier circuitry.

### BACKGROUND

### Field

Embodiments of the present disclosure generally relate to a loop testing. In particular embodiments herein relate to a dual high speed loopback testing circuitry with voltage level shifting and multiplexing

### Description of the Related Art

Integrated circuits (ICs) usually include a combination of analog and digital circuitries formed on a semiconductor substrate. Typically, ICs include complex circuitries that include billions of circuit elements, such as transistors, input/output (I/O) pins, or the like in a very small area making ICs low cost and high performance. Circuit elements can include defects or degrade over time. Typically to test and monitor performance of an IC loopback testing (described herein as “loopback”) is used. Loopback circuitries are a means for testing a circuit. Loopback is the routing of electronic signals back to their source without any processing or modification to ensure each of the circuit elements do not include any defect or degradation. However, due to the small area requirements for ICs, there is limited area availability for loopback circuitries, and loopback circuitries suffer from reliability and power delivery issues, and issues with voltage level shifting issues.

### SUMMARY

According to one or more examples, a loopback testing circuitry includes a pre-driver circuitry comprising a first source follower (SF) circuitry, and a loopback circuitry electronically connected to the pre-driver circuitry, the loopback circuitry comprising a second source follower (SF) circuitry and a current mode logic (CML) amplifier circuitry, wherein outputs of the first SF circuitry and outputs of the second SF circuitry are each electrically connected to the CML amplifier circuitry.

According to one or more examples, a loopback circuitry includes a first source follower (SF) circuitry, and a current mode logic (CML) amplifier circuitry, wherein one or more inputs of the CML amplifier circuitry are electrically connected to outputs of the first SF circuitry and outputs of a second SF circuitry included in a pre-driver circuitry.

According to one or more examples, A loopback testing circuitry includes a mission path, a PAD mode path, and a pre-driver loopback path including a pre-driver circuitry comprising a first source follower (SF) circuitry, a loopback circuitry electrically connected to the pre-driver circuitry, the loopback circuitry including a second source follower (SF) circuitry; and a current mode logic (CML) amplifier circuitry, wherein outputs of the first SF circuitry and outputs of the second SF circuitry are each electrically connected to the CML amplifier circuitry.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a loopback testing circuitry, according to one or more examples.

FIG. 2 illustrates the loopback testing circuitry according to one or more examples.

FIG. 3 illustrates a pre-driver circuitry 110 of the loopback testing circuitry 100, according to one or more examples.

FIG. 4 illustrates source follower (SF) circuitries of the loopback testing circuitry, according to one or more examples.

FIG. 5 illustrates a current mode logic (CML) amplifier circuitry, according to one or more examples.

FIG. 6 illustrates a loopback termination circuitry, according to one or more examples

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Loopback circuitries are a means for testing a circuit. Loopback is the routing of electronic signals back to their source without any processing or modification. Integrated circuits (ICs) include complex circuitries that include up to billions of circuit elements such as transistors, input/output pins or the like. Typically, ICs are produced in large batches on a single wafer and then are diced into individual ICs. Each IC includes billions of circuit elements in a very small area making each of the ICs low cost and high performances. However, during the fabrication of ICs the cause circuit elements to have defects or the circuit elements can degrade over time. To ensure each of the circuit elements do not include any defect or degradation on die loopback circuitries are used to perform loopback testing (herein described as loopback). Loopback is the routing of electronic signals back to their source without any processing or modification to ensure each of the circuit elements do not include any defect or degradation. As will be described in more detail below, due to the small area requirements for ICs, there is limited area availability for loopback circuitries, and loopback circuitries suffer from reliability and power delivery issues, and issues with voltage level shifting. Embodiments herein relate to a high-speed loopback circuitry that can provide voltage level shifting and multiplexing that can support a target data rate within the small area requirements of an IC with an improved reliability and power delivery.

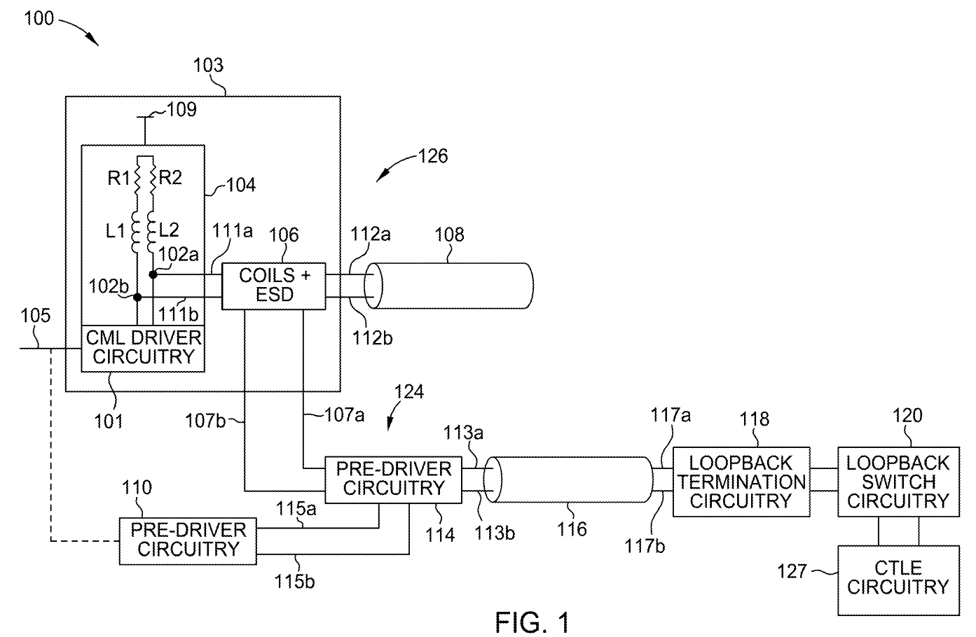

FIG. 1 illustrates a loopback testing circuitry 100, according to one or more examples. In one or more examples, the loopback testing circuitry 100 serves as test link between a transmitter (TX) and a receiver (RX). In one or more examples, the loopback testing circuitry 100 includes a driver circuitry 103, a pre-driver circuitry 110, a loopback circuitry 114, a loopback termination circuitry 118, a loopback switch circuitry 120 (e.g., a pass gate), and a continuous time linear equalization (CTLE) circuitry 127 (e.g., a CTLE filter).

The driver circuitry 103 includes an NMOS based current mode logic (CML) driver circuitry 101, a calibrated on die termination (ODT) circuitry 104, and sets of inductor coils and electro-static diodes (ESDs) 106. In one or more examples, the ODT resistance of the ODT circuitry 104 is from about 40 Ohms to about 60 Ohms, for example 50 Ohms. The CML driver circuitry 101 and the ODT circuitry 104 are respectively electrically connected to a node 102a and a node 102b that are each electrically connected to the sets of inductor coils and ESDs 106. In one or more examples, an electrical signal 111a is transmitted from the node 102a to the sets of inductor coils and ESDs 106. An electrical signal 111b is transmitted from the node 102b to the sets of inductor coils and ESDs 106.

The CML driver circuitry 101 is also is electrically connected to (e.g., receives an input from) a serializer output 105. In one or more examples, the serializer output 105 is configured to output a stream of data having any suitable length, such as 8-bits of data, to the CML driver circuitry 101. In one or more examples, the driver circuitry 103 operates on a voltage supply 109 of about 1.4V to about 1.6 V, for example 1.5 V. In one or more embodiments, the loopback circuitry loading on the driver circuitry 103 is less than 60 fF at 1 GHz.

Electrical signals are transmitted from of the sets of inductor coils and ESDs 106 to a transmission line 108 and the loopback circuitry 114 (e.g., the sets of inductor coils and ESDs 106 are electrically connected to the transmission line 108 and the loopback circuitry 114). The sets of inductor coils and ESDs 106 transmit a driver output 107a and a driver output 107b to the loopback circuitry 114. Stated differently, the driver circuitry 103 is electrically connected to the transmission line 108 and the loopback circuitry 114. In one or more examples, the transmission line 108 is within a data line and is non-terminated during loopback.

Although the ODT circuitry 104, the CML driver circuitry 101, and the sets of inductor coils and ESDs 106 are illustrated as having two inputs and outputs, this is for example purposes only. It is understood that the ODT circuitry 104, the CML driver circuitry 101, and the sets of inductor coils and ESDs 106 (i.e., the driver circuitry 203) can have any suitable quantity of outputs and inputs.

The loopback circuitry 114 is also electrically connected to the pre-driver circuitry 110. The loopback circuitry 114 receives the driver output 107a and the driver output 107b from the driver circuitry 103 or pre-driver output 115a and pre-driver output 115b from the pre-driver circuitry 110 based on the mode of operation currently being used by the loopback circuitry 114. The loopback circuitry 114 transmits an output 113a and an output 113b (i.e., is electrically connected) to a transmission line 116. In one or more examples, the transmission line 116 is a differential transmission line within a data line and has a length up to 1.2 mm.

The pre-driver circuitry 110 is electrically connected to (receives an input from) the serializer output 105 and provides pre-driver output 115a and pre-driver output 115b to the loopback circuitry 114. The transmission line 116 is further electrically connected (transmits outputs) to the loopback termination circuitry 118 which is further electrically connected to (transmits outputs) the loopback switch circuitry 120. In one or more examples, the transmission line transmits output 117a and 117b to the loopback termination circuitry 118.

In one or more examples, the loopback testing circuitry 100 includes three paths that each corresponding to a mode of operation. The loopback testing circuitry 100, includes a mission path 126, a pre-driver loopback path 122, and a PAD mode path 124. The loopback testing circuitry 100 is able to operate in three different modes, mission mode, pre-driver loopback mode and PAD mode. When operating in mission mode (e.g., regular operation), the loopback testing circuitry 100 utilizes the mission path 126. The mission path includes the driver circuitry 103 and the transmission line 108. It is understood that when operating in mission mode the transmission line is not terminated at loopback and the electrical signals at the node 112a and the node 112b are tapped and provided to additional circuitry.

When operating in PAD mode, the loopback testing circuitry 100 utilizes the PAD mode path 124. The PAD mode path 124 includes (in order) the driver circuitry 103, the loopback circuitry 114, the transmission line 116, the loopback termination circuitry 118, the loopback switch circuitry 120, and the CTLE circuitry 127.

When operating in pre-driver loopback mode the loopback testing circuitry 100 utilizes the pre-driver loopback path 122. The pre-driver loopback path includes (in order) the pre-driver circuitry 110, the loopback circuitry 114, the transmission line 116, the loopback termination circuitry 118, the loopback switch circuitry 120, and the CTLE circuitry 127. The loopback circuitry 114 can only operate in one or mission mode, pre-driver loopback mode or PAD mode. Stated differently, mission mode, pre-driver loopback mode and PAD mode are mutually exclusive. The loopback testing circuitry 100 can support both pre-driver loopback mode and PAD mode at a data-rate up to 224 Gbps PAM4/ 112 GBPS NRZ.

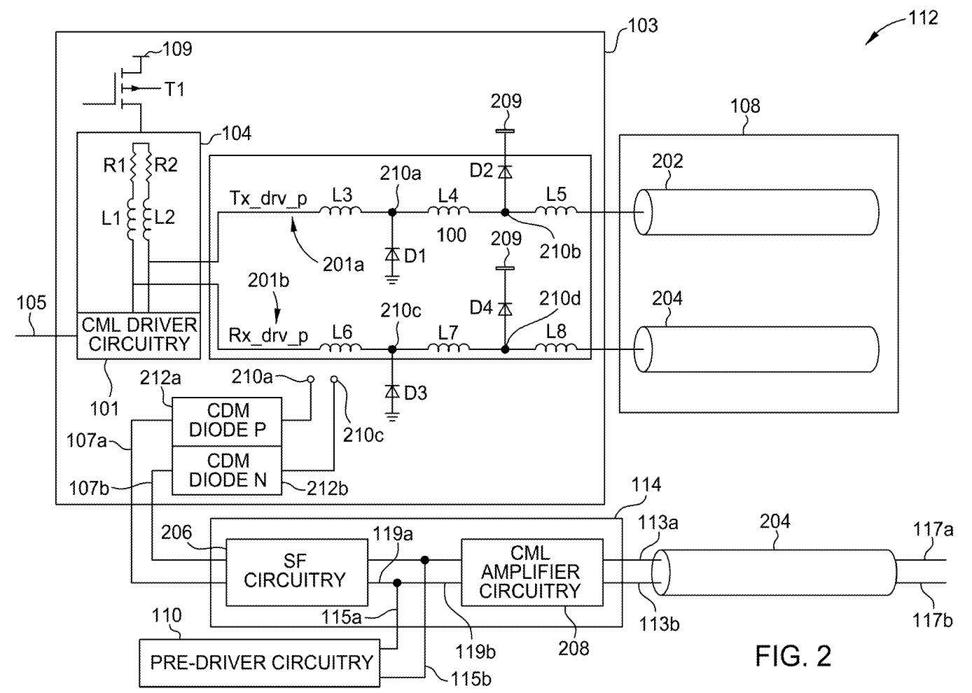

FIG. 2 illustrates the loopback testing circuitry 100, according to one or more examples. In one or more examples, as illustrated in FIG. 2, the sets of inductor coils and ESDs 106, and therefore, the driver circuitry 103 further include two different paths. The transmission line 108 further includes a transmission line 202 and a transmission line 204. Furthermore, the voltage supply 109 and the ODT circuitry 104 are electrically connected to a transistor T1. The transistor T1 may be any suitable type of transistor, including, but not limited to, a p-type MOSFET having a drain electrode electrically connected to the voltage supply 109 and a source electrode electrically connected to the ODT circuitry 104.

A path 201a of the sets of inductor coils and ESDs 106 includes an inductor L3, an inductor L4, an inductor L5, a diode D1, and a diode D2. The inductor L3, the inductor L4, and the inductor L5, respectively, are electrically connected in-series. The inductor L3 is electrically connected between the node 102a and the inductor L4. The inductor L4 is electrically connected between the inductor L3 and the inductor L5. The inductor L5 is electrically connected between the inductor L4 and the transmission line 202 (i.e., the end of the path 201a). The diode D1 is electrically connected to a node 210a that is located between the inductor L3 and the inductor L4. The cathode of the diode D1 is electrically connected to the node 210a and the anode of the diode D1 is grounded. The diode D2 is electrically connected to a node 210b that is located between the inductor L4 and the inductor L5. The cathode of the diode D2 is electrically connected to a voltage supply 209 that provides a voltage from about 1.03V to about 1.15V and the anode of the diode D2 is electrically connected to the node 210b. In one or more examples, the diode D1 and the diode D2 are ESDs.

A path 201b of the sets of inductor coils and ESDs 106 includes an inductor L6, an inductor L7, an inductor L8, a diode D3, and a diode D4. The inductor L6, the inductor L7, and the inductor L8, respectively, are electrically connected in-series. The inductor L6 is electrically connected between the node 102b and the inductor L7. The inductor L7 is electrically connected between the inductor L6 and the inductor L8. The inductor L8 is electrically connected between the inductor L7 and the transmission line 204 (i.e., the end of the path 201b). The diode D3 is electrically connected to a node 210c that is located between the inductor L6 and the inductor L7. The cathode of the diode D3 is electrically connected to the node 210b and the anode of the diode D3 is grounded. The diode D4 is electrically connected to a node 210d that is located between the inductor L7 and the inductor L8. The cathode of the diode D4 is electrically connected to the voltage supply 209 and the anode of the diode D4 is electrically connected to the node 210d. In one or more examples, the diode D3 and the diode D4 are ESDs.

The driver circuitry 103 further includes charged device model (CDM) diodes. In one or more examples, a CDM diode is electrically connected to each path of the sets of inductor coils and ESDs 106. A CDM diode 212a has an input that is electrically connected to the node 210a and an output that is electrically connected to the loopback circuitry 114. A CDM diode 212b has an input that is electrically connected to the node 210c and an output that is electrically connected to the loopback circuitry 114. The CDM diode 212a provides the driver output 107a to the loopback circuitry 114. The CDM diode 212b provides the driver output 107b to the loopback circuitry 114. Stated differently, the driver circuitry 103 provides two outputs to the loopback circuitry 114. Although one CDM diode is electrically connected to each path, this is for example purposes only and any suitable quantity of CDM diode(s) can be electrically connected to each path. Although the sets of inductor coils and ESDs 106 are illustrating as having two paths, this is for example purposes only, and the sets of inductor coils and ESDs 106 may include any suitable quantity of paths (and therefore, the driver circuitry 103 may provide any suitable quantity of outputs to the loopback circuitry 114).

In one or more examples, the loopback circuitry 114 further includes a source follower (SF) circuitry 206 and a CML amplifier circuitry 208. The input of the SF circuitry 206 is electrically connected to the outputs of the CDM diode 212a and the CDM diode 212b. The outputs of the SF circuitry 206 are electrically connected to the inputs of the CML amplifier circuitry 208. In one or more examples, the outputs of the SF circuitry 206 include output 119a and output 119b. The inputs of the CML amplifier circuitry 208 are electrically connected to the outputs of the pre-driver circuitry 110 and the outputs of the SF circuitry 206. As will be described in more detail below the outputs 119a and 119b of the SF circuitry 206 can be shorted by the outputs of the pre-driver circuitry. As shown in FIG. 2, during PAD mode loopback, tapping is performed post diode (i.e., the tapped nodes 210a, 210c, are post diodes D1, and D3) from the non-terminated side, which provides full ESD support and full driver signal coverage. Advantageously, the SF circuitry 206 (i.e., the first stage of the loopback circuitry 114) allows for shifting of the voltage common mode (VCM) from a higher potential to a lower potential. Additionally, gate protection of the SF circuitry 206 is provided by the use of CDM diodes (i.e., CDM diode 212a and CDM diode 212b).

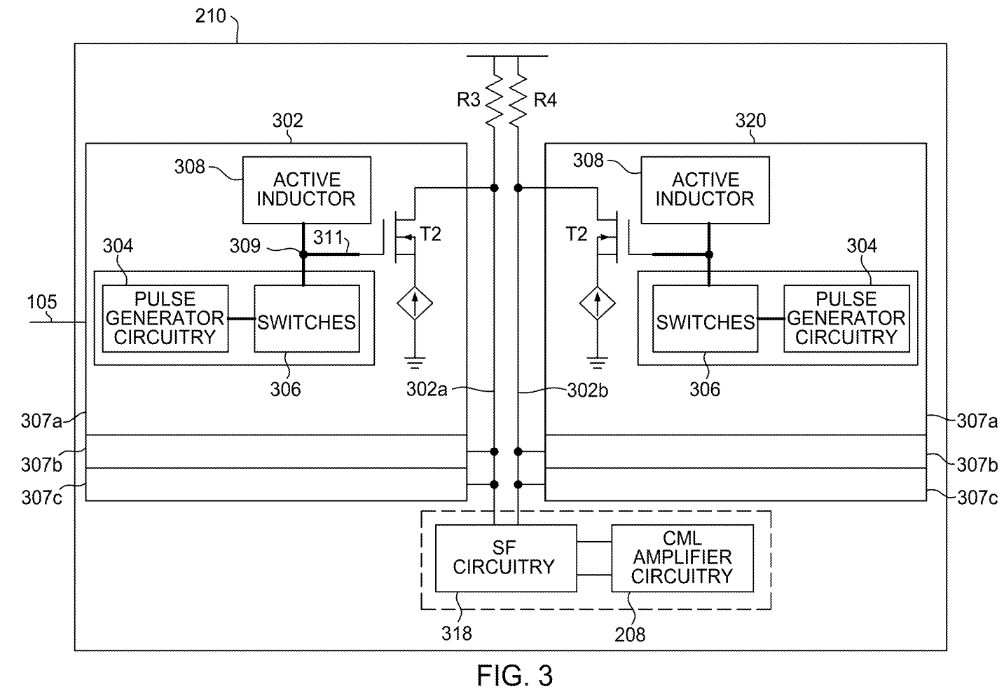

FIG. 3 illustrates a pre-driver circuitry 110 of the loopback testing circuitry 100, according to one or more examples. As noted above, the pre-driver circuitry 110 receives the serializer output 105. In one or more examples, the pre-driver circuitry 110 includes a drive-out circuitry 302 that includes a pulse generator circuitry 304, a bank of switches 306, an active inductor circuitry 308, and driver array slice circuitries. In one or more examples, the drive-out circuitry 302 includes three driver array slice circuitries, a least significant bit (LSB0) driver array slice circuitry 307a, a most significant bit driver array slice circuitry (MSB0) 307b, and a MSB0 driver array slice circuitry 307c. Any combination of driver array slice circuitries can be included in the drive-out circuitry 302. Although the drive-out circuitry 302 illustrates three driver array slice circuitries, this is for example purposes only, and any suitable quantity of driver array slice circuitries can be included in the drive-out circuitry 302.

The pulse generator circuitry 304 is electrically connected to the bank of switches 306. In one or more examples, the quantity of switches included in the bank of switches 306 is equal to the quantity of outputs of the pulse generator circuitry 304. For example, the pulse generator is an 8:4 pulse generator circuitry 304 and the bank of switches 306 includes four switches. Although an 8:4 pulse generator circuitry is described herein, this is for example purposes only, and the pulse generator circuitry 304 can have any ratio of inputs to outputs and the bank of switches 306 can include any suitable quantity of switches. The bank of switches 306 and the active inductor circuitry 308 are both electrically connected to a node 309. An electrical signal 311 is transmitted from the node 309 to the gate of the transistor T2. Thus, the node 309 is electrically connected to the gate of the transistor T2. The drive-out circuitry 302 is electrically connected and provides outputs to a pull-up termination circuitry 310. In one or more examples, the pull-up termination circuitry 310 is a resistor-based pull-up termination circuitry. The drive-out circuitry 302 is electrically connected to the pull-up termination circuitry 310. In one or more examples, the drain of the transistor T2 is electrically connected to the pull-up termination circuitry 310 and the driver array slice circuitries are electrically connected to the pull-up termination circuitry 310. The pull-up termination circuitry 310 is electrically connected to a SF circuitry 318, which provides pre-driver outputs 115a and 115b to the loopback circuitry 114.

Additionally, the pull-up termination circuitry 310 is further electrically connected to a drive-out circuitry 320. The drive-out circuitry 320 includes the same components as the drive-out circuitry 302 and transmits a drive-out circuitry output 302b to the pull-up termination circuitry 310. Stated differently, the pull-up termination circuitry 310 transmits the drive-out circuitry output 302a and/or the drive-out circuitry output 302b to the SF circuitry 318. The SF circuitry 318 is described in more detail below.

As noted above, when in pre-driver loopback mode, the electrical signal 311 at the node 309 is tapped before reaching the transistor T2. Thus, the drive-out circuitry output 302a is the outcome of combining non-overlapping pulse at full data-rate from the pulse generator circuitry 304. The driver array slice circuitries are in functional mode and current sum 1 LSB and 2 MSB data using a local termination to supply, thereby generating the PAM4 signal. The PAM4 signal VCM is set such that an SF circuitry, (e.g., SF circuitry 318) in PAD-mode can be re-used along with good balanced DC gain and Nyquist AC gain.

In one or more examples, the pull-up termination circuitry 310 is parallel to the ODT circuitry 104 (e.g., the about 55 Ohm to voltage supply 109) and is used provide an electrical signal to the SF circuitry 318 which provides pre-driver outputs 115a and 115b to the CML amplifier circuitry 208, which in turn, outputs (transmits) electrical signals to the transmission line 116 that is electrically connected the loopback termination circuitry 118. The input voltage common mode the CTLE circuitry 127 has a specific range of voltage requirement for better gain and linearity, which can be achieved using this termination scheme. The loopback switch circuitry 120 is used to isolate the signal during mission mode to the CTLE circuitry 127 where the loopback signal from TX is injected into the RX.

As noted above, the transmission line 116 has a length of approximately 1.2mm and drives the loopback signal from the TX to the RX. This routing is done at greatest signal metal with less resistance and capacitance (self + coupling) to attain better return loss and insertion loss at Nyquist frequencies including, but not limited about 14GHz, 28 GHz, and 56GHz, or the like.

As noted above, loopback architectures have issues with voltage level shifting, limited area availability, long transmission lines) and reliability and power delivery issues. The driver circuitry 103 includes a CML based architecture is operating on a supply voltage of about 1.5V during loopback mode and the ODT circuitry has an ODT resistance of 50 Ohms. The CML driver circuitry 101 is an NMOS driver with a stage that is the same as the driver slice circuitries of the pre-driver circuitry 110. Thus, the driver output 107a and the driver output 107b will have a VCM from about 0.9 V to about 1 V that needs to be stepped down to meet the CTLE circuitry 127 input VCM range requirement of about 0.4 V to about 0.5 V after (post) the loopback switch circuitry 120.

Additionally, in PAD mode and pre-driver loopback mode, the swing of the electrical signals provided to the loopback circuitry 114 (e.g., driver output 107a and driver output 107b) are non-rail to rail with different VCM levels. Thus, an improved level shifting and multiplexer (MUX) of both modes supporting the data-rate is required.

The electrical signals (e.g., the output 113a and the output 113b) provided by the loopback circuitry 114 must be driven through a long route (e.g., the transmission line 116 having a length of less than or equal to 1.2 mm) having a low resistance of about less than Ohms and a low extracted capacitance. The transmission line 116 has a length, DC resistance, and extracted capacitance are based on the S-parameter values and the DC resistance has to be lower through the transmission line 116 to meet the required VCM range at of the CTLE circuitry 127. Therefore, because the size of the transmission line cannot be shortened it is a challenge to support a Nyquist frequency up-to 56 GHz within a confined area allowable for the loopback circuitry 114. Additionally the CTLE circuitry 127 gain that can be achieved is about 6dB around Nyquist while there is only 1 CTLE circuitry stage along with an ACG stage of about 6dB to 8dB gain is available. Thus, there is a tighter specification on the loss of the signal allowed from the TX to RX CTLE circuitry path.

In the pre-driver loopback mode, electrical signal 311 (FIG. 3) will be a NRZ signal obtained based on the non-overlapping 4 pulse input transmitted to the bank of switches 306 from the pulse generator circuitry 304. Due to limited area available and to reduce the complexity of combining both the PAD mode path 124 and the pre-driver loopback path 122 before reaching the transmission line 116, the loopback testing circuitry 100 should be chosen to balance between the performance, reliability, and power delivery network aspects.

In the pre-driver loopback path 122, the SF circuitry 206 uses lower gate length (core) circuitry devices (including, but not limited to, circuitry devices for lower technologies nodes such as less than 6 nm gate length FINFET devices), and the voltage stress handling capability of these circuitry devices will be violated during mission mode of driver where the highest signal swing can be around 1.3V. To protect this condition extra circuitry to maintain a constant bias on the drain/source of the device during PAD mode with loopback OFF must to be used.

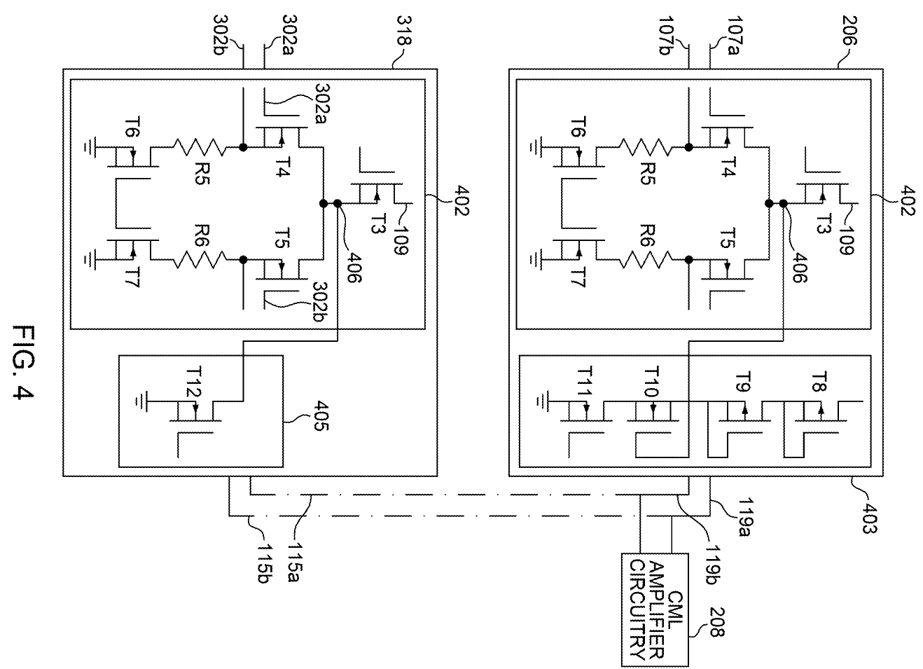

FIG. 4 illustrates source follower (SF) circuitries of the loopback testing circuitry 100, according to one or more examples. Stated differently, FIG. 4 illustrates the SF circuitry 206 and the SF circuitry 318. In one or more examples, the SF circuitry 318 is an NMOS stage with a resistor-based load 402. The SF circuitry 206 receives inputs (e.g., driver output 107a and driver output 107b) from the driver circuitry 103. The voltage common mode (VCM) inputs received from the driver circuitry 103 are from about 0.9 V to about 1.1 V, for example from about 0.9V to about 1 V, using either NRZ or PAM4 signal supporting up-to Baud rate 112 GBaud. In one or more examples, the transconductance and load resistor values of the resistor-based load 402 are selected to maintain the bandwidth and output VCM suitable for the CML amplifier circuitry 208 (e.g., the second stage of the loopback circuitry 114). When the loopback circuitry 114 is OFF, and the loopback testing circuitry 100 is operating in mission mode, the greatest swing voltage at the input of the SF circuitry 206 is about 1.35 V, which can cause electrical stress. To avoid the stress, the SF circuitry 206 includes an off-circuitry 403 that is electrically connected to a node 406. In one or more examples, the off-circuitry 403 is a transistor based resistor divider circuitry. In one or more examples, the node 406 is set to a voltage by the off-circuitry 403 that is less than received the driver output 107a and the driver output 107b. Furthermore, the transistors T6 and T7 are set to a voltage of 0 (i.e., the path to ground is disconnected) when the loopback is OFF (mission mode) causing a potential difference between the voltage at the node 406 and the driver output 107a and the driver output 107b to be less than what is allowed of the technology limit (e.g., less than 0.96 V).

The outputs 119a and 119b transmitted by the SF circuitry 206 are shorted by the pre-driver outputs 115a and 115b because the pre-driver output 115a and output 119a, and the pre-driver output 115b and the output 119b are respectively electrically connected together and transmitted as the inputs of the CML amplifier circuitry 208. The SF circuitry 318 includes the same resistor-based load 402 as the SF circuitry 206. The SF circuitry 318 includes an off-circuitry 405. In one or more examples, the off-circuitry 405 is a pull-down to ground circuitry. Thus, the off-circuitry 405 is different from the off-circuitry 403 because the off-circuitry 403 is a transistor based resistor divider circuitry while the off-circuitry 405 is in a pull-down to ground circuitry.

In one or more examples, the dual SF circuitries 206, 318 act as a multiplexer. Stated differently, while the Off-circuitry 403 operates to protect T4 and T5 which receives inputs from the driver output 107a and the driver output 107b and operates at a higher swing voltage, at this time pre driver-out circuitry output 302a and drive-out circuitry output 302b can become floating by turning OFF the transistor T2 in the pre-driver circuitry 210, thus the transistor T12 of the off-circuitry 405 acts as a pull-down switch, thereby forming a no contention on multiplexer output. The SF circuitries 206, 318 are each electrically connected to the voltage supply 109. Another advantage of using the SF circuitries 206, 318 (low output impedance) is combing the data from both the loopback modes is feasible without much circuit complexity and bandwidth degradation relatively.

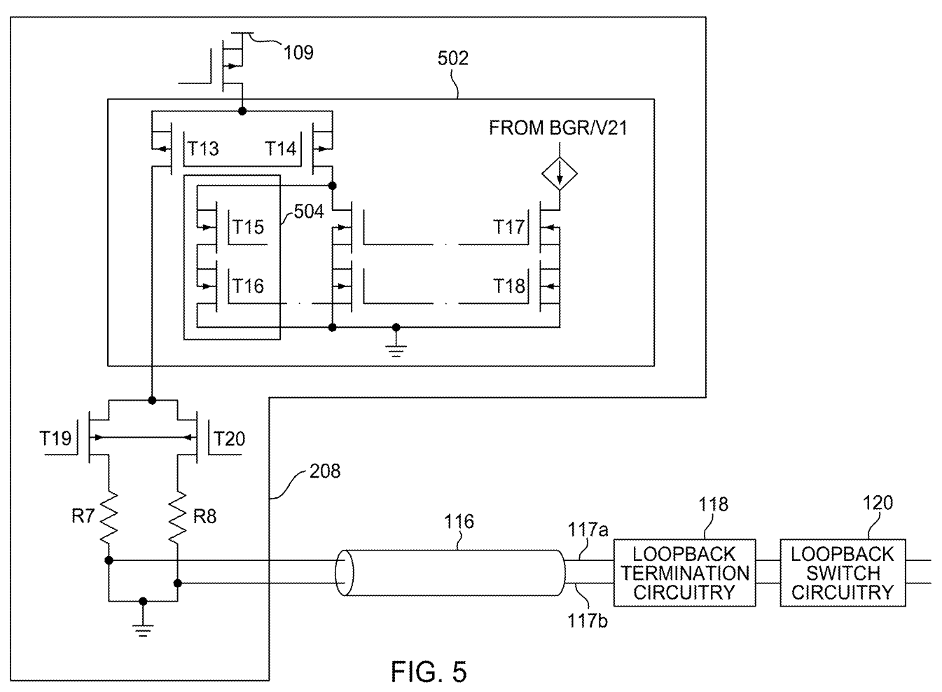

FIG. 5 illustrates a current mode logic (CML) amplifier circuitry 208, according to one or more examples. As noted above the second stage of the loopback circuitry 114 is the CML amplifier circuitry 208. In one or more examples, the CML amplifier circuitry 208 in PMOS based. The CML amplifier circuitry 208 provides a low frequency gain of about 3dB to about 6dB, for example about 4.5 db. The CML amplifier circuitry 208 needs to recover the losses from the CDM diode 212a and 212b and the SF circuitries 206, 318 with a good bandwidth to drive its self-loading and the load from the transmission line 116. The gain of the CML amplifier circuitry 208 cannot be too high because in would affect the linearity of the PAM4 signal and the output common mode which in-turn changes the VCM at the input of the CTLE circuitry 127.

To meet the input VCM range of from about 0.4V to about 0.5V, a current mirror circuitry 502 provides the bias to the CML amplifier circuitry 208 that is varied using a 4-bit binary input control thereby allowing 16 combinations of current steps. The current mirror circuitry 502 gets a VC based 100uA of current from the Bandgap/V2I circuitry which is again multiplied to attain a current of about 24mA to about 40 mA.

Advantageously, the number of stages in the loopback circuitry 114 path is limited (2-stages) due to the CML amplifier circuitry 208-based architecture, thus reducing the area of the loopback testing circuitry 100. Furthermore, using the SF circuitries 206, 318 and the CML amplifier circuitry as the stages of the loopback circuitry 114, provides a better control over the current being drawn during the pre-driver loopback mode.

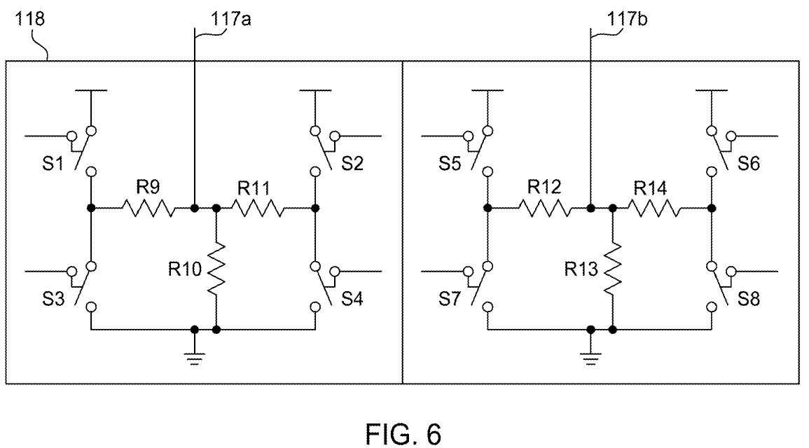

FIG. 6 illustrates a loopback termination circuitry 118, according to one or more examples. In one or more examples, the loopback termination circuitry 118 includes a 2-bit trim option with pull-up and pull-down switches (S1-S4) along with high resistors (R9-R11) in parallel which provides a VCM adjustment of about 350 mV to about 490 mV, for example 50mV without affecting the effective impedance seen. When the switches S1-S4 are open, the effective impedance is targeted to be about 55 Ohms including the routings to the transmission line. When the switches S1-S4 are closed, the effective impedance will be about 46 ohms there by providing a 2-step impedance option.

The loopback testing circuitry 100 provides multiple advantages. A first advantage is that a VCM correction is achieved using open loop mode, current trim inputs controlled through firmware. Furthermore, a closed loop solution can also be achieved with availability of more area for the supporting circuits and voltage sensing from the RX side after the loopback switch circuitry 120.

In one or more examples, the extra load cap on the driver circuitry 103 can be greater than 60fF and affect the driver circuitry 103. Furthermore, in the pre-driver circuitry 110 the driver array slice circuitries 307a-307c, provide a limitation on the load the pre-driver circuitry 110 can drive. Advantageously, the SF circuitries 206 and 318 leads to the benefit of controlling the load cap, aiding the level shifting of the VCM without too much loss on the signal bandwidth compared to other topologies like gm-gm based or AC level shifters.

Another advantage is that, the number of stages in the loopback circuitry 114 path is limited (2-stages) due to the CML amplifier circuitry 208-based architecture, thus reducing the area of the loopback test circuitry 100. Furthermore, using the SF circuitries 206, 318 and the CML amplifier circuitry 208 as the stages of the loopback circuitry 114 provides a better control over the current being drawn during the pre-driver loopback mode because the SF circuitries 206, 318 and the CML amplifier circuitry 208 share the same voltage supply 109 from an LDO used by the driver circuitry 103, and allow for the combing of data from both the loopback modes to be feasible without much circuit complexity and bandwidth degradation relatively. Furthermore, because the SF circuitries 206, 318 and the CML amplifier circuitry 208 are electrically connected to a single regulated power supply 109, which allows for stronger supply and ground grids as the area is restricted and narrow.

Furthermore, the VCM correction which presently is with an open loop scheme, and the circuitry implemented for the same doesn’t load the high-speed data signal path on the TX side as it is based on the current. Advantageously, the loopback testing circuitry 100 allows for a closed loop implementation that can be implemented using few extra circuits with the existing trim bits without affecting the data path.

Additionally, the loopback testing circuitry 100 provides a VCM correction range is from about 350mV to about 490mV including the TX current trimming and the RX side termination-based trim. An isolation between TX mission mode driver signal on to the RX CTLE circuitry 127 when the loopback is turned off is about 85dB, an insertion loss of the transmission line 116 of about 8dB at the Nyquist frequency of about 56GHz. The RX side termination scheme (the loopback termination circuitry plus the loopback termination switches) provides 2 effective impedance values, one at about 55 ohms when the switches are off and second of about 46 ohms. This option can be used for increasing the TX side data swing.

While the foregoing is directed to specific examples, other and further examples may be devised without departing from the basic scope thereof, and the scope thereof is determined by the claims that follow.

What is claimed is:

1. A loopback testing circuitry comprising:
a pre-driver circuitry comprising a first source follower (SF) circuitry; and
a loopback circuitry electronically connected to the pre-driver circuitry, the loopback circuitry comprising a second SF circuitry and a current mode logic (CML) amplifier circuitry, wherein outputs of the first SF circuitry and outputs of the second SF circuitry are each electrically connected to the CML amplifier circuitry.

2. The loopback testing circuitry of claim 1, wherein the pre-driver circuitry further comprises a pull-up termination circuitry that is electronically connected to a first drive-out circuitry and a second drive-out circuitry, wherein the first drive-out circuitry and the second drive-out circuitry each comprise: a least significant bit driver array slice circuitry, a first most significant bit driver array slice circuitry, and a second most significant bit driver array slice circuitry.

3. The loopback testing circuitry of claim 2, wherein the first drive-out circuitry and the second drive-out circuitry further comprise a pulse generator circuitry electrically connected to a bank of switches that is electrically connected to an active inductor circuitry that is electrically connected to the pull-up termination circuitry.

4. The loopback testing circuitry of claim 1, wherein the first SF circuitry includes an off-circuitry that is a pull-down to ground circuitry.

5. The loopback testing circuitry of claim 1, wherein the second SF circuitry includes an off-circuitry that is a transistor based resistor divider circuitry.

6. The loopback testing circuitry of claim 1, wherein the first SF circuitry and the second SF circuitry include a same NMOS stage with a resistor-based load.

7. The loopback testing circuitry of claim 1, further comprising a mission path, a pre-driver loopback path, and a PAD mode path.

8. The loopback testing circuitry of claim 7, wherein the mission path comprises a driver circuitry electrically connected to a non-terminated transmission line.

9. The loopback testing circuitry of claim 8, wherein the driver circuitry comprises a CML driver circuitry, a calibrated on die termination (ODT) circuitry, and sets of inductor coils and electro-static diodes (ESDs).

10. The loopback testing circuitry of claim 7, wherein the pre-driver loopback path comprises the pre-driver circuitry, the loopback circuitry, a transmission line, a loopback termination circuitry, a loopback switch circuitry, and a continuous time linear equalization (CTLE) circuitry.

11. The loopback testing circuitry of claim 10, wherein the transmission line has a length less than or equal to 1.2 mm.

12. The loopback testing circuitry of claim 10, wherein the PAD mode path includes a driver circuitry, the loopback circuitry, the transmission line, the loopback termination circuitry, the loopback switch circuitry, and the CTLE circuitry.

13. A loopback circuitry comprising:
a first source follower (SF) circuitry; and
a current mode logic (CML) amplifier circuitry, wherein one or more inputs of the CML amplifier circuitry are electrically connected to outputs of the first SF circuitry and outputs of a second SF circuitry included in a pre-driver circuitry.

14. The loopback circuitry of claim 13, wherein the second SF circuitry includes an off-circuitry that is a pull-down to ground circuitry.

15. The loopback circuitry of claim 13, wherein the first SF circuitry includes an off-circuitry that is a transistor based resistor divider circuitry.

16. The loopback circuitry of claim 13, wherein the first SF circuitry and the second SF circuitry include a same NMOS stage with a resistor-based load.

17. A loopback testing circuitry comprising:
a mission path;
a PAD mode path; and
a pre-driver loopback path comprising:
a pre-driver circuitry comprising a first source follower (SF) circuitry;
a loopback circuitry electrically connected to the pre-driver circuitry, the loopback circuitry comprising:
a second SF circuitry; and
a current mode logic (CML) amplifier circuitry, wherein outputs of the first SF circuitry and outputs of the second SF circuitry are each electrically connected to the CML amplifier circuitry.

18. The loopback testing circuitry of claim 17, wherein the loopback testing circuitry is configured to use the mission path during mission mode, the PAD mode path during PAD mode, and the pre-driver loopback path during pre-driver loopback mode, and wherein mission mode, PAD mode, and pre-driver loopback mode are mutually exclusive.

19. The loopback testing circuitry of claim 17, wherein the first SF circuitry includes a first off-circuitry that is a pull-down to ground circuitry, and the second SF circuitry includes a second off-circuitry that is a transistor based resistor divider circuitry.

20. The loopback testing circuitry of claim 1, wherein the first SF circuitry and the second SF circuitry include a same NMOS stage with a resistor-based load.
